(19) United States
(12) Patent Application Publication
(10) Pub. No.: US 2014/0328363 A1
(43) Pub. Date: Nov. 6, 2014

(54) RIDGE WAVEGUIDE SEMICONDUCTOR LASER DIODE AND METHOD FOR MANUFACTURING THE SAME

(71) Applicant: Electronics and Telecommunications Research Institute, Daejeon (KR)

(72) Inventors: Oh Kee KWON, Daejeon (KR); Chul-Wook LEE, Daejeon (KR); Yongsoon BAEK, Daejeon (KR)

(73) Assignee: Electronics and Telecommunications Research Institute, Daejeon (KR)

(21) Appl. No.: 14/147,923

(22) Filed: Jan. 6, 2014

(30) Foreign Application Priority Data
May 2, 2013 (KR) 10-2013-0049542

(51) Int. Cl. H01S 5/026; H01S 5/22

(52) U.S. Cl. CPC H01S 5/0262; H01S 5/22
USPC 372/45.01; 438/31

(57) ABSTRACT

Provided is a method of manufacturing a ridge waveguide type semiconductor laser diode, the method including sequentially forming, on a substrate, a lower clad layer, an active layer, a first upper clad layer, and a second upper clad layer; forming an insulating mask on the second upper clad layer; wet-etching the second upper clad layer by using the insulating mask to form channels passing through the second upper clad layer and a ridge between the channels; and performing dry-etching by using the insulating mask to form trenches that are extended from the channels and pass through the first upper clad layer.

### CROSS-REFERENCE TO RELATED APPLICATIONS

This U.S. non-provisional patent application claims priority under 35 U.S.C. §119 to Korean Patent Application No. 10-2013-0049542, filed on May 2, 2013, the entire contents of which are hereby incorporated by reference.

### BACKGROUND OF THE INVENTION

Embodiments of the present inventive concepts relate to semiconductor laser diodes and methods for manufacturing the same, and more particularly, to semiconductor laser diodes having ridge-type waveguides.

Recently, a high output-power semiconductor laser has used in various fields, such as a pumping source for an optical fiber amplifier, optical communication, medical treatment, and a display. As an example, a semiconductor laser lasing at a wavelength of 0.98 μm has been used as a pumping source for an erbium (Er) doped optical fiber amplifier. Such an optical fiber amplifier increases in optical amplification factor as optical output power increases. To this end, the high optical coupling efficiency between the semiconductor laser and an optical fiber is needed as well as high output power of the semiconductor laser that is the pumping source.

For the high output power of the semiconductor laser, a ridge waveguide (RWG) type structure has been widely used. The reason for this is that its optical density in terms of optical output power is lower as compared to other structures and thus a catastrophic optical damage (COD) level is high.

The ridge waveguide operates by using an index guide scheme in which an optical characteristic is determined by a vertical effective refractive index difference between a ridge and both sides of a ridge. However, since the ridge waveguide is a laterally weak index guide type in which the vertical effective refractive index difference is small in a lateral direction, there is a limitation in that beam steering occurs. The beam steering indicates a fluctuation in the distribution of output lights due to a carrier-induced refractive index change when operating at high output power. The reason for this is that when operating at high output power by high driving currents, the lateral strength distribution (lateral mode) of an active layer is transited, from a fundamental lateral mode in which strength decreases gradually from the center of a ridge waveguide, to a higher order lateral mode in which there are several maximum points in strength distribution. This irregularly alters efficiency related to optical coupling to an optical fiber as well as optical output power of a semiconductor laser. Thus, there is a limitation in that availability as a pumping source of a ridge type semiconductor laser decreases when operating at high output power.

### SUMMARY OF THE INVENTION

The present inventive concepts relates to a ridge waveguide type semiconductor laser diode and a method of manufacturing the same that inhibit higher order lateral mode lasing in order to restrain beam steering appearing when operating at high output power in a ridge waveguide type semiconductor laser.

Embodiments of the present inventive concepts provide methods of manufacturing a ridge waveguide type semiconductor laser diode, the method including sequentially forming, on a substrate, a lower clad layer, an active layer, a first upper clad layer, and a second upper clad layer; forming an insulating mask on the second upper clad layer; wet-etching the second upper clad layer by using the insulating mask to form channels passing through the second upper clad layer and a ridge between the channels; and performing dry-etching by using the insulating mask to form trenches that are extended from the channels and pass through the first upper clad layer.

In some embodiments, the method may further include forming an etch stop layer between the first upper clad layer and the second upper clad layer, wherein the wet-etching may be performed until the etch stop layer is exposed.

In other embodiments, the ridge may be formed in a reverse mesa structure in which a lower width of the ridge is narrower than an upper width of the ridge.

In still other embodiments, a width of the trenches may be formed more narrowly than a lower width of the channels.

In even other embodiments, the trenches may be formed to expose a top of the active layer.

In yet other embodiments, the trenches may pass through the active layer, and a portion of the lower clad layer may be etched to form the trenches.

In other embodiments of the present inventive concepts, ridge waveguide type semiconductor laser diodes include a substrate; a lower clad layer, an active layer, a first upper clad layer, and a second upper clad layer sequentially formed on the substrate; a ridge defined at the second upper clad layer by channels passing through the second upper clad layer; and trenches extended from the channels and passing through the first upper clad layer.

In some embodiments, the ridge waveguide type semiconductor laser diode may further include an etch stop layer disposed between the first upper clad layer and the second upper clad layer.

In other embodiments, the ridge may have a reverse mesa structure in which a lower width of the ridge is narrower than an upper width of the ridge.

In still other embodiments, a width of the trenches may be narrower than a lower width of the channels.

In even other embodiments, the trenches may expose a top of the active layer.

In yet other embodiments, the trenches may be extended to an inside of the lower clad layer through the active layer.

### BRIEF DESCRIPTION OF THE DRAWINGS

The accompanying drawings are included to provide a further understanding of the present inventive concepts, and are incorporated in and constitute a part of this specification. The drawings illustrate exemplary embodiments of the present inventive concepts and, together with the description, serve to explain principles of the present inventive concepts. In the drawings:

FIG. 1 is a perspective view of a ridge waveguide type semiconductor laser diode according to an embodiment of the present inventive concepts;

FIG. 2 is a perspective view of a ridge waveguide type semiconductor laser diode according to another embodiment of the present inventive concepts;

FIGS. 3 to 7 are sectional views for explaining a method of manufacturing a ridge waveguide type semiconductor laser diode according to an embodiment of the present inventive concepts; and

FIG. 8 is a sectional view for explaining a method of manufacturing a ridge waveguide type semiconductor laser diode according to another embodiment of the present inventive concepts.

### DETAILED DESCRIPTION OF PREFERRED EMBODIMENTS

Exemplary embodiments are described below in detail with reference to the accompanying drawings. Advantages and features of the present inventive concepts, and implementation methods thereof will be clarified through following embodiments described with reference to the accompanying drawings. The present inventive concepts may, however, be embodied in different forms and should not be construed as limited to the embodiments set forth herein. Rather, these embodiments are provided so that this disclosure will be thorough and complete, and will fully convey the scope of the present inventive concepts to those skilled in the art. Further, the present inventive concepts are only defined by scopes of claims. Like reference numerals refer to like elements throughout.

In the following description, the technical terms are used only for explaining specific embodiments while not limiting the present inventive concepts. The terms of a singular form may include plural forms unless referred to the contrary. The meaning of “include,” “ comprise,” “including,” or “comprising,” specifies a property, a region, a fixed number, a step, a process, an element and/or a component but does not exclude other properties, regions, fixed numbers, steps, processes, elements and/or components. Since exemplary embodiments are provided below, the order of the reference numerals given in the description is not limited thereto. It will be understood that when an element such as a layer, film, region, or substrate is referred to as being “on” another element, it can be directly on the other element or intervening elements may also be present.

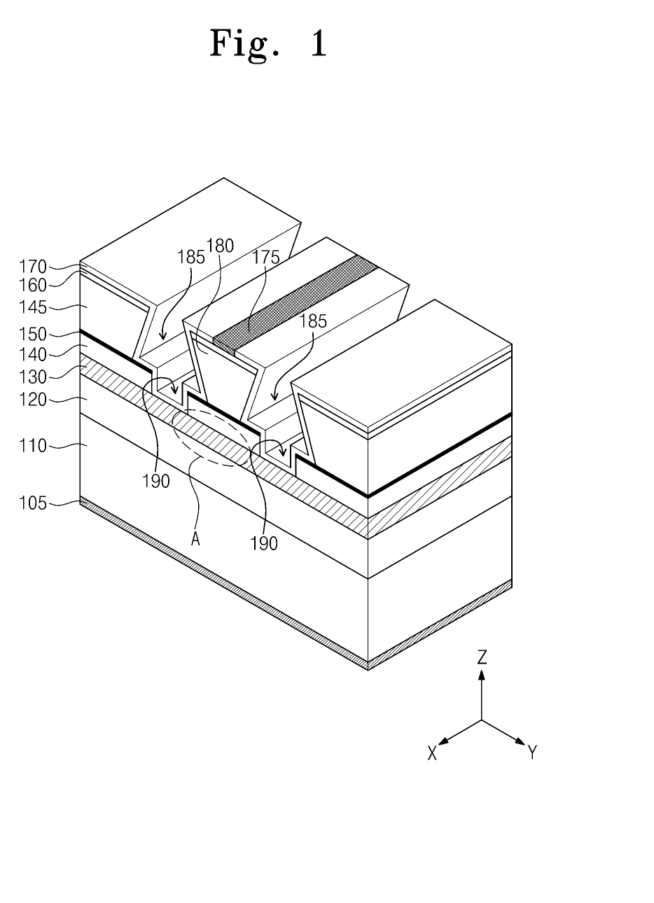

FIG. 1 is a perspective view of a ridge waveguide type semiconductor laser diode according to an embodiment of the present inventive concepts.

Referring to FIG. 1, the ridge waveguide type semiconductor laser diode according to an embodiment of the present inventive concepts may include a lower clad layer 120, an active layer 130, a first upper clad layer 140, and a second upper clad layer 145 that are sequentially provided on a substrate 110. Also, an etch stop layer 150 may be disposed between the first upper clad layer 140 and the second upper clad layer 145.

The substrate 110 may be a compound semiconductor. As an example, the substrate 110 may include indium phosphide (InP) or gallium arsenide (GaAs). The active layer 130 may have a multiple quantum well structure having strain or lattice matching. As an example, the active layer 130 may be a multiple quantum well structure including indium gallium arsenide phosphide (InGaAsP), indium gallium aluminum arsenide (InGaAlAs), aluminum gallium arsenide (AlGaAs), gallium arsenide (GaAs) and/or indium gallium arsenide (InGaAs). The lower clad layer 120, the first upper clad layer 140, and the second upper clad layer 145 may use a material that has a refractive index lower than that of the active layer 130 and that is lattice matched with the active layer 130. The lower clad layer 120 may be a n type, and the first upper clad layer 140 and the second upper clad layer 145 may be a p type. The first upper clad layer 140 and the second upper clad layer 145 may include the same material. As an example, the lower clad layer 120, the first upper clad layer 140, and the second upper clad layer 145 may include Indium phosphide (InP), aluminum gallium arsenide (AlGaAs), or indium gallium phosphide (InGaP). The etch stop layer 150 may include indium gallium arsenide phosphide (InGaAsP), aluminum gallium arsenide (AlGaAs), or indium gallium phosphide (InGaP).

A ridge 180 may be defined at the upper clad layer 145 by channels 185 passing through the upper clad layer 145. That is, the ridge 180 is a protruded part that is arranged on the first upper clad layer 140 and formed from the second upper clad layer 145. In an embodiment, the ridge 180 may be a reverse mesa structure in which a lower width of the ridge 180 is narrower than an upper width thereof. A metal contact layer 160 may be arranged on the ridge 180 and the second upper clad layer 145. The metal contact layer 160 may include indium gallium arsenide (InGaAs) or gallium arsenide (GaAs).

Trenches 190 are regions that are extended from the channels 185 toward the substrate 110 and pass through the first upper clad layer 140. The width of the trenches 190 may be narrower than the lower width of the channels 185.

In the present embodiment, the ridge waveguide type semiconductor laser diode may include a structure of a shallow RWG in which the first upper clad layer 140 is passed through by the trenches 190. As an example, the shallow RWG structure may be used for an active device, such as an optical amplifier or a laser diode.

The ridge waveguide type semiconductor laser diode may include an insulating layer 170 on the ridge 180. The insulating layer 170 may be silicon dioxide film (SiO₂) or silicon nitride film (Si₃N₄). A p-type electrode layer 175 may be disposed on the ridge 180 and an n-type electrode layer 105 may be disposed at the bottom of the substrate 110. The p-type electrode layer 175 and the n-type electrode layer 105 may include a metal thin film

The operation principle of the ridge waveguide type semiconductor laser diode according to the embodiment of the present inventive concepts is as follows.

If an anode and a cathode are connected to the p-type electrode 175 and the n-type electrode 105, respectively and currents are injected in the forward directions, charges are converted into light by charge accumulation at a region A of the active layer 130 under the ridge 180 where pn junction is made, and thus optical gain arises. The light emitted by optical gain is focused on the center of the active layer 130 by a difference in refractive index of each layer in a vertical direction (z direction) and by the difference between the effective refractive indexes of the ridge 180 part and the channels 185 part in a horizontal direction (y direction). In this case, if injected currents increase to operate the ridge waveguide type semiconductor laser diode at high output power, the refractive index of the ridge 180 part decreases due to an increase in optical output power of the ridge 180 part. Thus, the difference between the effective refractive indexes of the ridge 180 part and the channels 185 part and a single later mode operation may fail. In the case of the ridge waveguide type semiconductor laser diode according to the embodiment of the present inventive concepts, the trenches 190 extended from the channels 185 are formed on both sides of the ridge 180 to form an additional refractive index difference in addition to the effective refractive index difference. Thus, it is possible to maintain a single lateral mode operation even in high output power operation and inhibit higher order lateral mode lasing. As a result, beam steering may be restrained.

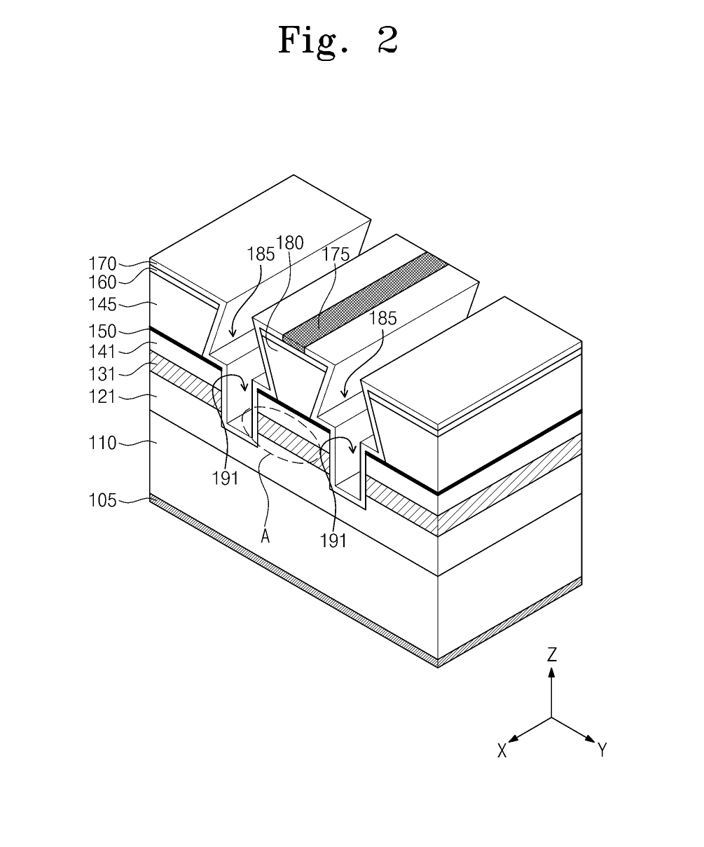

FIG. 2 is a perspective view of a ridge waveguide type semiconductor laser diode according to another embodiment of the present inventive concepts. For simplicity of description, the same components are not described.

Referring to FIG. 2, the ridge waveguide type semiconductor laser diode according to the preset embodiment may include a structure of a deep RWG in which trenches 191 are extended to the inside of the lower clad layer 121 through the first upper clad layer 141 and the active layer 131. In this case, the bottom of the trenches 191 may be about 1 μm away from the bottom of the active layer 131. As an example, the deep RWG structure may also be used for a passive device, such as an optical waveguide, a modulator or a phase controller in addition to an active device, such as a laser diode or an optical amplifier.

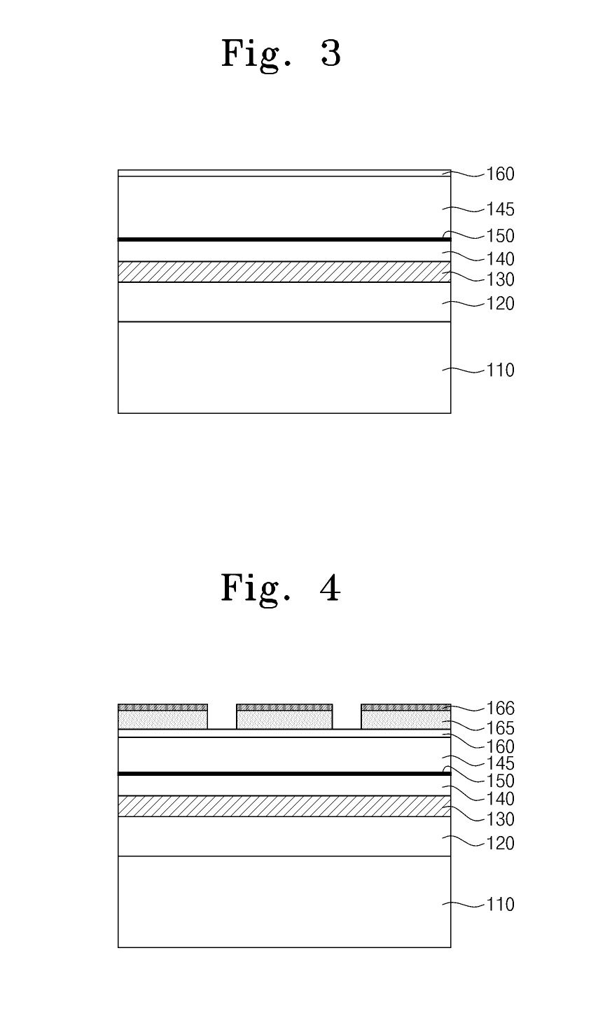

FIGS. 3 to 7 are sectional views for explaining a method of manufacturing a ridge waveguide type semiconductor laser diode according to an embodiment of the present inventive concepts.

Referring to FIG. 3, the lower clad layer 120, the active layer 130, the first upper clad layer 140, the second upper clad layer 145, and the metal contact layer 160 may be sequentially formed on the substrate 110. In an embodiment, the etch stop layer 150 may be further disposed between the first upper clad layer 140 and the second upper clad layer 145.

The substrate 110 may be a compound semiconductor. As an example, the substrate 110 may include indium phosphide (InP) or gallium arsenide (GaAs). The active layer 130 may have a multiple quantum well structure having strain or lattice matching. As an example, the active layer 130 may be a multiple quantum well structure including indium gallium arsenide phosphide (InGaAsP), indium gallium aluminum arsenide (InGaAlAs), aluminum gallium arsenide (AlGaAs), gallium arsenide (GaAs) and/or indium gallium arsenide (InGaAs). The lower clad layer 120, the first upper clad layer 140, and the second upper clad layer 145 may include a material that has a refractive index lower than that of the active layer 130 and that is lattice matched with the active layer 130. The lower clad layer 120 may be doped with an n-type dopant, and the first upper clad layer 140 and the second upper clad layer 145 may be doped with a p-type dopant. The first upper clad layer 140 and the second upper clad layer 145 may include the same material. As an example, the lower clad layer 120, the first upper clad layer 140, and the second upper clad layer 145 may include indium phosphide (InP), aluminum gallium arsenide (AlGaAs), or indium gallium phosphide (InGaP). The etch stop layer 150 may include indium gallium arsenide phosphide (InGaAsP), aluminum gallium arsenide (AlGaAs), or indium gallium phosphide (InGaP). The metal contact layer 160 may include indium gallium arsenide (InGaAs) or gallium arsenide (GaAs).

In an embodiment, Metal-organic vapor phase epitaxy (MOVPE) may be used as a technique for forming the layers 120, 130, 140, 145, 150 and 160.

Referring to FIG. 4, an insulating mask 165 may be formed on the metal contact layer 160. The insulating mask 165 may be formed through a photolithography process and an etching process using a photoresist 166. In an embodiment, the insulating mask 165 may be a silicon dioxide film (SiO₂) or a silicon nitride film (Si₃N₄).

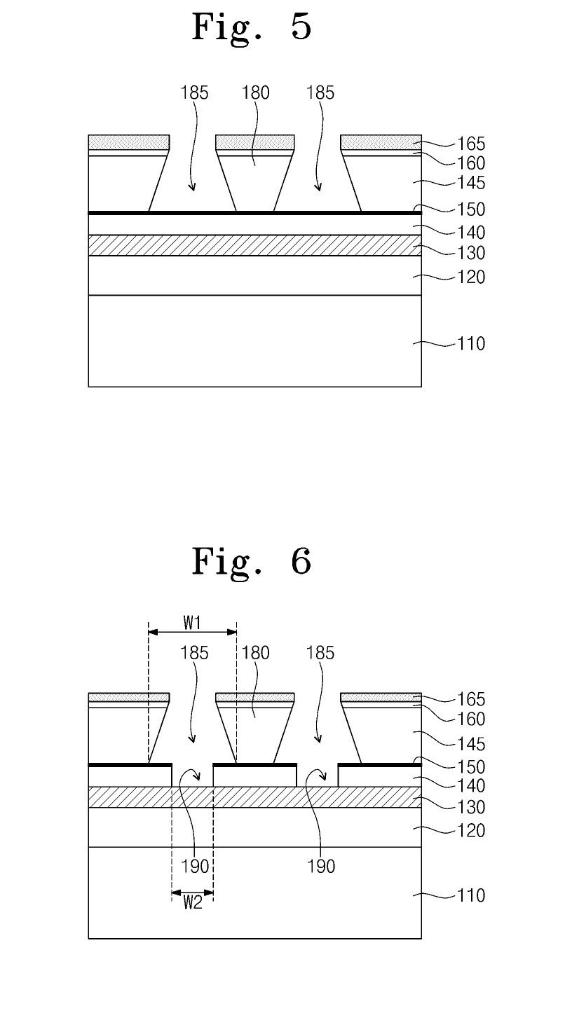

Referring to FIG. 5, by wet-etching the metal contact layer 160 and the second upper clad layer 145 by using the insulating mask 165, it is possible to form the ridge 180 between the channels 185 passing through the metal contact layer 160 and the second upper clad layer 145 and adjacent channels 185. The channels 185 and the ridge 180 may be formed on the first upper clad layer 140. In an embodiment, the wet-etching may be performed until the etch stop layer 150 is exposed. Thus, the bottom of the channels 185 may be defined by the etch stop layer 150. In an embodiment, the wet-etching may use etchant in which hydrogen bromide (HBr) and phosphoric acid (H₃PO₄) are mixed, or etchant in which hydrogen chloride (HCl) and phosphoric acid (H₃PO₄) are mixed. In an embodiment, the ridge 180 may have a reverse mesa structure in which the lower width of the ridge 180 is narrower than the upper width thereof.

Referring to FIG. 6, the insulating mask 165 remaining after the wet-etching may be used to perform dry-etching so that trenches 190 may be formed, which are extended from the channels 185 toward the substrate 110 and pass through the first upper clad layer 140. The width W2 of the trenches 190 may be formed more narrowly than the lower width W1 of the channels 185. In the present embodiment, the ridge waveguide type semiconductor laser diode may be manufactured in a structure of a shallow RWG that is formed to expose the top of the active layer 130 by the trenches 190. Since the trenches 190 are formed in a self-alignment manner by using a mask used in the wet-etching process without manufacturing a separate mask for forming the trenches 190, a manufacturing process may be simplified.

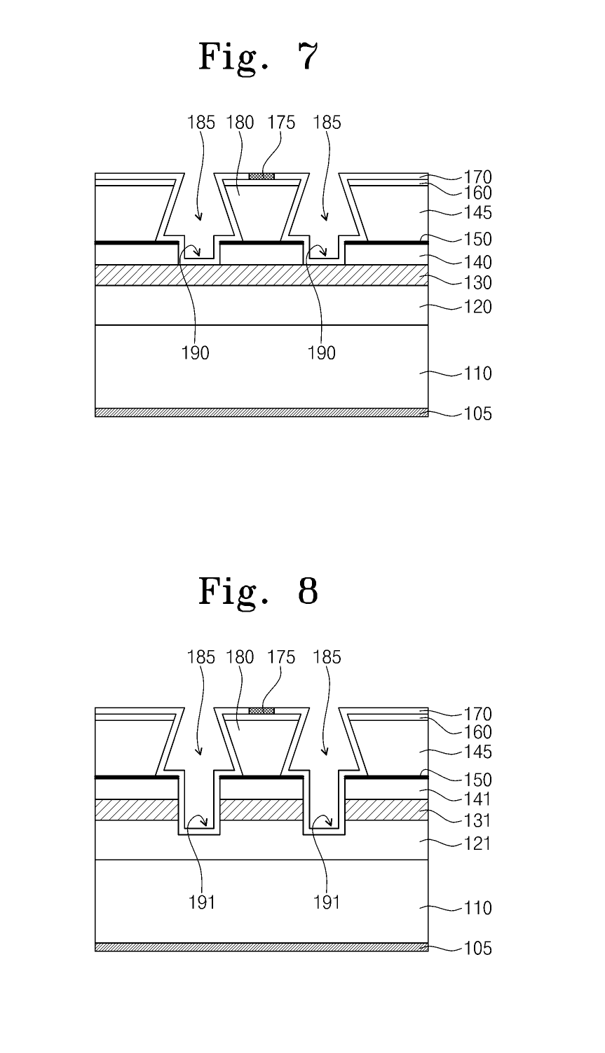

Referring to FIG. 7, the insulating mask 165 remaining after forming the trenches 190 in FIG. 6 may be removed and an insulating layer 170 may be formed on the top of the structure that the insulating mask 165 has been removed. The insulating layer 170 may be a silicon dioxide film (SiO₂) or a silicon nitride film (Si₃N₄). A p-type electrode layer 175 may be formed on the ridge 180 and an n-type electrode layer 105 may be formed at the bottom of the substrate 110. When forming the p-type electrode layer 175 and the n-type electrode layer 105, a lift-off process and a plating process may be performed.

According to the method of manufacturing the ridge waveguide type semiconductor laser diode according to an embodiment of the present inventive concepts, the trenches 190 are formed in a self-alignment manner by using a mask used in forming the ridge 180 without manufacturing a separate mask for forming the ridge 180, a manufacturing process may be simplified. Furthermore, the trenches 190 may be symmetrically formed on both sides of the ridge 180. Also, since the dry-etching technique for forming the trenches 190 does not affect an alteration in material characteristic of the active layer 130, a device yield may be enhanced.

FIG. 8 is a sectional view for explaining a method of manufacturing a ridge waveguide type semiconductor laser diode according to another embodiment of the present inventive concepts. For simplification of description, the same components of the manufacturing method are not described.

Referring to FIG. 8, a dry-etching process may be formed on the result that is described with reference to FIG. 5. The dry-etching process may be performed by using an insulating mask (not shown) remaining after the wet-etching process. Trenches 191 may be formed which are extended from the channels 185 toward the substrate 110 by using the dry-etching process and pass through the first upper clad layer 141 and the active layer 131. In the present embodiment, the ridge waveguide type semiconductor laser diode may be manufactured in a structure of a deep RWG because a portion of the lower clad layer 121 is together etched when forming the trenches 191. The dry-etching may be performed by about 1 μm from the bottom of the active layer 131. After forming the trenches 191, the processes described with reference to FIG. 7 are performed to complete the ridge waveguide type semiconductor laser diode.

As described above, according to the embodiments of the present inventive concepts, a reverse mesa ridge is formed on the first upper clad layer, and trenches that are extended from the channels and pass through the first upper clad layer are formed on both sides of the ridge. Thus, the semiconductor laser diode according to the embodiments of the present inventive concepts has an effect of inhibiting higher order lateral mode lasing in high output power operation by forming an additional index difference in a lateral direction on both sides of the ridge and thus beam steering may be restrained. Also, dry-etching is performed by using a self-alignment scheme without a separate mask manufacturing process when forming the trenches so that a manufacturing process may be simplified.

While embodiments of the present inventive concepts are described with reference to the accompanying drawings, those skilled in the art will be able to understand that the present inventive concepts may be practiced as other particular forms without changing essential characteristics. Therefore, embodiments described above should be understood as illustrative and not limitative in every aspect.

What is claimed is:

1. A method of manufacturing a ridge waveguide type semiconductor laser diode, the method comprising:
sequentially forming, on a substrate, a lower clad layer, an active layer, a first upper clad layer, and a second upper clad layer;
forming an insulating mask on the second upper clad layer;
wet-etching the second upper clad layer by using the insulating mask to form channels passing through the second upper clad layer and a ridge between the channels; and
performing dry-etching by using the insulating mask to form trenches that are extended from the channels and pass through the first upper clad layer.

2. The method of claim 1, further comprising forming an etch stop layer between the first upper clad layer and the second upper clad layer, wherein the wet-etching is performed until the etch stop layer is exposed.

3. The method of claim 1, wherein the ridge is formed in a reverse mesa structure in which a lower width of the ridge is narrower than an upper width of the ridge.

4. The method of claim 1, wherein a width of the trenches is formed more narrowly than a lower width of the channels.

5. The method of claim 1, wherein the trenches are formed to expose a top of the active layer.

6. The method of claim 1, wherein the trenches pass through the active layer, and wherein a portion of the lower clad layer is etched to form the trenches.

7. A ridge waveguide type semiconductor laser diode comprising:
a substrate;
a lower clad layer, an active layer, a first upper clad layer, and a second upper clad layer sequentially formed on the substrate;
a ridge defined at the second upper clad layer by channels passing through the second upper clad layer; and
trenches extended from the channels and passing through the first upper clad layer.

8. The ridge waveguide type semiconductor laser diode of claim 7, further comprising an etch stop layer disposed between the first upper clad layer and the second upper clad layer.

9. The ridge waveguide type semiconductor laser diode of claim 7, wherein the ridge has a reverse mesa structure in which a lower width of the ridge is narrower than an upper width of the ridge.

10. The ridge waveguide type semiconductor laser diode of claim 7, wherein a width of the trenches is narrower than a lower width of the channels.

11. The ridge waveguide type semiconductor laser diode of claim 7, wherein the trenches expose a top of the active layer.

12. The ridge waveguide type semiconductor laser diode of claim 7, wherein the trenches are extended to an inside of the lower clad layer through the active layer.
